(19) United States
(12) Patent Application Publication
(10) Pub. No.: US 2005/0140534 A1
(43) Pub. Date: Jun. 30, 2005

(54) Resistance voltage divider circuit, liquid crystal display driving apparatus using resistance voltage divider circuit, and liquid crystal display apparatus

(75) Inventors: Kazuyoshi Nishi, Mukou-shi (JP); Masahide Murata, Takaoka-shi (JP)

Correspondence Address: PARKHURST & WENDEL, L.L.P., 1421 PRINCE STREET, SUITE 210, ALEXANDRIA, VA, 22314-2805, US

(73) Assignee: Matsushita Elec. Ind. Co. Ltd., Kadoma-shi (JP)

(21) Appl. No.: 11/016,723

(22) Filed: Dec. 21, 2004

(30) Foreign Application Priority Data
Dec. 25, 2003 (JP) 2003-428511
Nov. 26, 2004 (JP) 2004-341341

(51) Int. Cl. H03M 1/78; G09G 3/20

(52) U.S. Cl. 341/154; 345/55; 345/92

(57) ABSTRACT

A resistance voltage divider circuit of a gradation potential generation circuit for adjustment, which generates a gradation potential for driving a liquid crystal device. The circuit includes three resistors (11) which are equal in resistance value and have contacts (12) at equal positions. The contacts (12) at the equal positions of each resistors (11) are connected to one another so as to connect the resistors in parallel, reference potentials V1 and V2 are inputted across the resistors connected in parallel, and a gradation potential is generated on a junction point of the contact (12) according to a voltage divided by the resistors (11).

### FIELD OF THE INVENTION

The present invention relates to a resistance voltage divider circuit included in a gradation voltage generation circuit.

### BACKGROUND OF THE INVENTION

A gradation voltage generation circuit generates a gradation voltage for driving a display device such as a liquid crystal element. For example, when a liquid crystal element is driven in a liquid crystal display apparatus, two or more reference voltages are first inputted to the gradation voltage generation circuit. The gradation voltage generation circuit minutely divides a voltage between the reference voltages so as to generate gradation voltages (or gradation voltages for γ correction) necessary for driving the liquid crystal element.

Further, more gradation voltages are necessary because display panels such as recent liquid crystal panels display more colors with higher definition. Thus, a voltage difference has decreased between adjacent gradations. This means that a gradation voltage generation circuit formed by resistors requires resistors having low resistance values with high accuracy.

For example, a known gradation voltage generation circuit is disclosed in Japanese Patent Laid-Open No. 11-95726. The gradation voltage generation circuit has a resistance voltage divider circuit comprising resistors which include a plurality of reference resistors connected in series. The resistance voltage divider circuit selects the junction points of the reference resistors among the resistors and connects selected reference points, so that the resistance values of voltage dividing resistors can be set minutely. A reference voltage is applied across the resistors to obtain a gradation voltage necessary for the connected reference points. Further, the gradation voltage generation circuit has a resistance wiring layer on each gradation voltage wiring layer via an interlayer insulating film. The gradation voltage wiring layer and the resistance wiring layer are connected to each other via a contact (or a through hole) to constitute each resistance voltage divider circuit.

Since it is better to have a lower resistance on the contact, the contact is generally made of a material having a low resistance value. One of the materials having low resistance values is a metal compound of silicon that is called silicide. Because of restrictions on the manufacturing of semiconductors, when the contact is silicified, a resistor under the contact is also silicified. Meanwhile, the resistor is made of a material other than silicide (hereinafter, referred to as non-silicide) in many cases to efficiently form a resistance component in a small area. Therefore, when the resistor is made of a material other than silicide, two materials of silicide and non-silicide are present in the resistor. It is known that a resistance component called an interface resistance appears on an interface between silicide and non-silicide and the interface resistance has a constant value regardless of a resistance range during the manufacturing of semiconductors.

When gradation voltages are minutely generated in the resistance voltage divider circuit, it is necessary to accurately generate resistance components with low resistance values. However, in the presence of a large interface resistance component on an interface between a resistor near a contact and an ordinary resistor, it is difficult to generate a low resistance value equal to or lower than the interface resistance.

### DISCLOSURE OF THE INVENTION

The present invention is devised to solve these problem and has as its object the provision of a resistance voltage divider circuit which can accurately form resistors with low resistance values and minutely generate gradation voltages even when a contact (or a through hole) and the resistor are made of different materials such as silicide and non-silicide and an interface resistance occurs on a boundary of the contact and the resistor, and provide a liquid crystal display driving apparatus and a liquid crystal display apparatus which use the resistance voltage divider circuit.

In order to attain the object, the resistance voltage divider circuit of the present invention comprises a plurality of resistors which are equal in resistance value and have contacts at equal positions, wherein the contacts at the equal positions of the resistors are connected to one another so as to connect the resistors in parallel, a reference voltage is inputted across the resistors connected in parallel, and a gradation voltage is generated on a junction point of the contact according to a voltage divided by the resistors.

With this configuration, the plurality of resistors having the contacts at the equal positions are connected in parallel, so that even when the resistors have a high interface resistance, it is possible to accurately generate the resistors with low resistance values. Therefore, it is possible to more minutely generate gradation voltages with high accuracy.

A liquid crystal display driving apparatus using the resistance voltage divider circuit of the present invention comprises the resistance voltage divider circuit and a DA converter circuit for outputting an analog voltage (driving voltage) according to a gradation voltage outputted from the resistance voltage divider circuit and an inputted digital command value.

With this configuration, the DA converter circuit outputs a gradation voltage outputted from the resistance voltage divider circuit, as an analog voltage corresponding to the digital command value, thereby driving the liquid crystal element according to an accurate gradation voltage. Therefore, it is possible to improve gradation display, that is, the quality of display on a liquid crystal panel and so on.

A liquid crystal display apparatus using the resistance voltage divider circuit of the present invention comprises a plurality of liquid crystal devises formed on a substrate, drive wires which are formed on the substrate and have the plurality of liquid crystal elements connected in a shared manner via a plurality of TFTs, and the liquid crystal display driving apparatus which is connected to the drive wires and drives the drive wires by outputting an analog voltage.

With this configuration, it is possible to apply an accurate gradation voltage (analog voltage) from the liquid crystal display driving apparatus to the drive wires of the liquid crystal elements. Therefore, it is possible to improve gradation display, that is, the quality of display on the liquid crystal display apparatus.

### BRIEF DESCRIPTION OF THE DRAWINGS

FIG. 1 is a structural diagram showing a resistance voltage divider circuit for a liquid crystal display driving apparatus according to Embodiment 1 of the present invention;

FIG. 2 is an explanatory drawing showing a parallel resistance of the resistance voltage divider circuit for the liquid crystal display driving apparatus;

FIG. 3 is a structural diagram showing a resistance voltage divider circuit for a liquid crystal display driving apparatus according to Embodiment 2 of the present invention;

FIG. 4 is a structural diagram showing a resistance voltage divider circuit for a liquid crystal display driving apparatus according to Embodiment 3 of the present invention;

FIG. 5 is a structural diagram showing a resistance voltage divider circuit for a liquid crystal display driving apparatus according to Embodiment 4 of the present invention;

FIG. 6 is a structural diagram showing a liquid crystal display driving apparatus of the present invention; and

FIG. 7 is a structural diagram showing a liquid crystal display apparatus of the present invention.

### DESCRIPTION OF THE EMBODIMENTS

Embodiments of the present invention will be described below in accordance with the accompanying drawings. All the following embodiments will describe examples in which a resistance voltage divider circuit of the present invention is applied to a liquid crystal display apparatus and a liquid crystal display driving apparatus.

### Embodiment 1

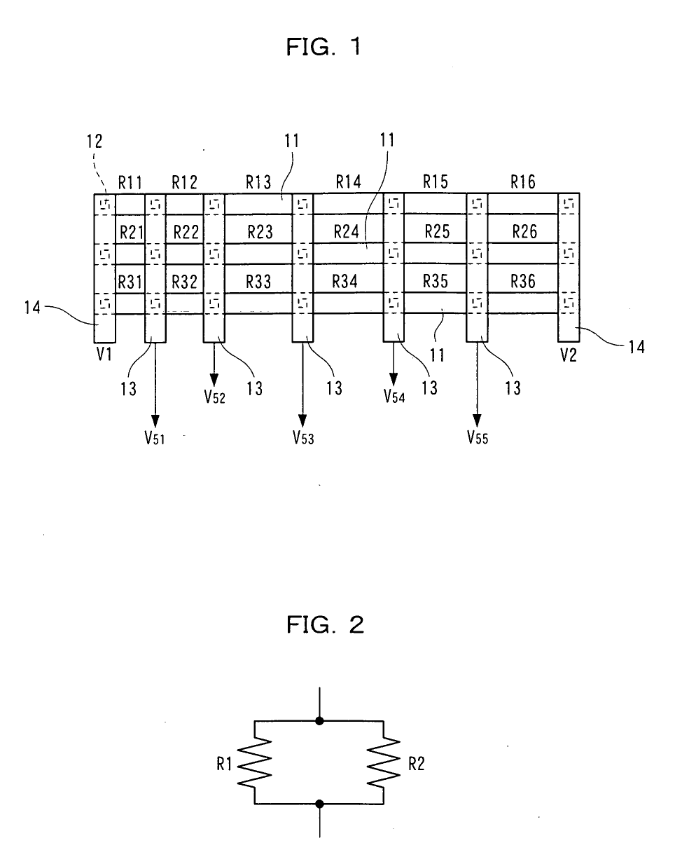

FIG. 1 is a structural diagram showing the resistance voltage divider circuit for a liquid crystal display driving apparatus (a resistance voltage divider circuit included in a gradation voltage generation circuit which generates a gradation voltage for driving a liquid crystal element) according to Embodiment 1 of the present invention.

As shown in FIG. 1, a plurality of (three in FIG. 1) resistors 11 are provided which are almost equal in resistance value and have a plurality of (seven in FIG. 1) contacts 12, on which gradation voltages are extracted, at the equal positions with respect to the horizontal direction of FIG. 1. Resistance values between the contacts 12 of the three resistors 11 have the relationship of R11:R12:R13: . . . :R16=R21:R22:R23: . . . :R26=R31:R32:R33: . . . :R36 where R11, R12, R13, . . . R16 represent resistance values between the contacts of a first resistor of the resistors 11, R21, R22, R23, . . . R26 represent resistance values between the contacts of a second resistor, and R31, R32, R33, . . . R36 represent resistance values between the contacts of a third resistor.

In a preferred embodiment, the plurality of resistors 11 are almost equal in resistance value. In this case, “almost equal” means that the resistance values of the plurality of resistors 11 are all regarded as equal as long as variations in manufacturing conditions are negligible in the manufacturing of semiconductors. For example, in the preferred embodiment, the resistors 11 are formed as wiring layers which are made of polysilicon or the like and are almost equal in length and width in the manufacturing of semiconductors, so that the resistors 11 are almost equal in resistance value. In the present specification, “almost equal” will comply with this use.

The contacts 12 at the equal positions of the resistors 11 are connected to one another via gradation voltage output wires 13 so as to connect the resistors 11 in parallel. Reference voltages V1 and V2 are inputted to reference voltage supply wires 14, which are provided on the contacts 12 on both ends of the resistors 11 connected in parallel, and gradation voltages V₅₁, V₅₂, V₅₃, V₅₄, and V₅₅ are generated on the junction points (wires 13) of the intermediate five contacts 12 according to voltages divided by the three resistors 11.

To be specific, the resistance voltage divider circuit shown in FIG. 1 is formed as follows:

First, the resistors 11 formed by N+ polysilicon resistors are provided on a substrate. Then, the gradation voltage output wires 13, which intersect the resistors 11 and are made of a material such as aluminum, are provided on the resistors 11 via an interlayer insulating film (not shown). Subsequently, the resistors 11 and the gradation voltage output wires 13 are connected via the contacts 12 made of a material having a low resistance value (e.g., a metal compound of silicon that is called silicide).

In the case of two parallel resistors shown in FIG. 2, the relationship of 1/RA=1/R1+1/R2 is established where RA represents a combined resistance and R1 and R2 represent resistance values. In the case of R1=R2=R, 1/RA=2/R, i.e., RA=R/2 is established which is obtained by dividing the original resistance value by the number of resistors. When N resistors of resistance value R are connected in parallel (N is a positive integer equal to or larger than 2), a combined resistance value RN is RN=R/N. Also in the case of R1≠R2, the relationship between R1 and R2 and the combined resistance RA satisfies R1>RA and R2>RA. Therefore, it is understood that the more resistors connected in parallel, the lower combined resistance.

According to the configuration of Embodiment 1, the three resistors 11 are provided on which resistance values are almost equal and the contacts 12 for extracting gradation voltages are arranged at the equal positions, the contacts 12 at the equal positions are connected via the gradation voltage output wires 13, and the resistors 11 are connected in parallel, so that the resistors 11 between the contacts 12 are connected in parallel and a resistance value between the contacts 12 can be reduced. Thus, even when a large resistance component (interface resistance) is present on an interface between the resistor 11 near the contact 12 and the resistors 11 on other areas, it is possible to accurately form resistors with low resistance values and minutely generate gradation voltages V₅₁, V₅₂, V₅₃, V₅₄, and V₅₅. Since the contacts 12 are arranged in lines, wiring for extracting gradation voltages from the contacts 12 can be formed with ease, thereby readily performing layout.

Embodiment 1 described the example of the three resistors 11. As is understood from the effect of the combined resistance, it is preferable to provide the two or more resistors 11. Further, Embodiment 1 described the example of the seven contacts 12 provided on the resistors 11. Even in the presence of an interface between silicide (the resistor 11 under the contact 12) and non-silicide (other than the resistor 11 under the contact 12), the effect of the present invention can be obtained by the resistors 11 configured using a combined resistance on non-silicide portions. That is, at least one contact 12 is necessary on the resistor 11 except for the contacts with the reference voltage supply wires 14. The effect of the present invention can be obtained by providing at least one gradation voltage output wire 13.

### Embodiment 2

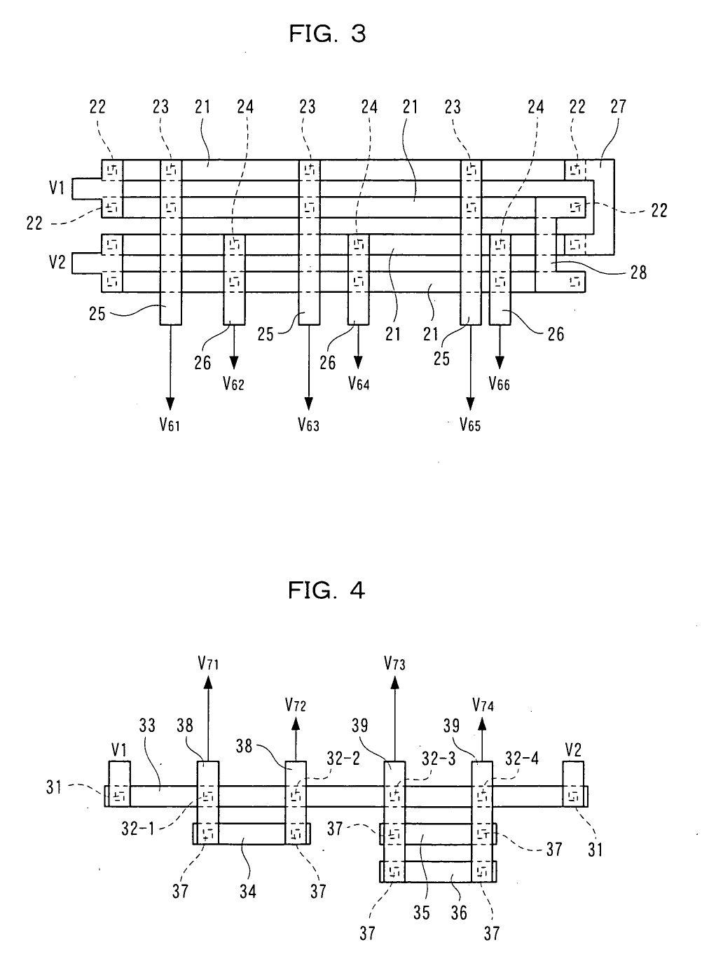

FIG. 3 is a structural diagram showing a resistance voltage divider circuit for a liquid crystal display driving apparatus according to Embodiment 2 of the present invention.

As shown in FIG. 3, 2N (N is an positive integer equal to or larger than 2) resistors 21 (four in FIG. 3) having almost equal resistance values are sequentially arranged in parallel with aligned longitudinal directions, and contacts 22 are provided on both ends of the resistors 21. Of the resistors 21 arranged in sequence, on the uppermost and second uppermost resistors 21 in FIG. 3, contacts 23 are provided at the equal positions with respect to the horizontal direction of FIG. 3. On the third and fourth uppermost resistors 21 in FIG. 3, contacts 24 are provided at the equal positions with respect to the horizontal direction of FIG. 3. The embodiment of FIG. 3 shows an example in which the positions of the contacts 24 are different from those of the contacts 23 with respect to the horizontal direction. No problem is presented even when the positions of the contacts 24 are the same as the contacts 23 with respect to the horizontal direction.

Further, the contacts 23 on the uppermost and second uppermost resistors 21 in FIG. 3 are connected to each other via gradation voltage output wires 25. The contacts 24 on the third and fourth uppermost resistors 21 in FIG. 3 are connected to each other via gradation voltage output wires 26. The contacts 22 on the ends of the odd-numbered resistors 21 (the uppermost and third uppermost resistors 21 in FIG. 3) are connected sequentially via a connecting wire 27. The contacts 22 on the ends of the even-numbered resistors 21 (the second and fourth uppermost resistors 21 in FIG. 3) are connected sequentially via a connecting wire 28.

The contacts 22 on the leading edges of the first and second resistors 21 are connected to each other, and the contacts 22 on the leading edges of the (2N−1)-th and 2N-th resistors 21 (third and fourth resistors 21 in FIG. 3) are connected to each other. Reference voltages V1 and V2 are inputted to the connected ends via reference voltage supply wires (not shown), and gradation voltages V₆₁, V₆₂, V₆₃, V₆₄, V₆₅ and V₆₆ are generated on the junction points (gradation voltage output wires 25) of the contacts 23 and the junction points (gradation voltage output wires 26) of the contacts 24 according to voltages. divided by the resistors 21.

To be specific, the resistance voltage divider circuit of FIG. 3 is formed as follows:

First, the resistors 21 formed by N+ polysilicon resistors are provided on a substrate. Then, the gradation voltage output wires 25 and 26 and the connecting wires 27 and 28, which intersect the resistors 21 and are made of a material such as aluminum, are provided on the resistors 21 via an interlayer insulating film (not shown). Subsequently, a resistance wiring layer and a gradation voltage wiring layer are connected via the contacts 22, 23, and 24 made of a material having a low resistance value (e.g., a metal compound of silicon that is called silicide).

Embodiment 2 is similar to the configuration of Embodiment 1 in a principle that the plurality of resistors 21 are connected in parallel to reduce a resistance value. In Embodiment 2, the odd-numbered resistors 21 are connected to each other and the even-numbered resistors 21 are connected to each other, that is, the 2N resistors 21 are alternately connected, thereby reducing the influence of in-plane variations in resistance during a process of manufacturing resistors.

When resistors are fabricated in the manufacturing of semiconductors, generally an impurity is diffused into a material of the resistors to control a resistance value. At this point, a concentration of the impurity is varied to a certain degree in a wiring layer which forms the resistors. For this reason, in the case of the resistors arranged in a simple manner as the layout of FIG. 1, the first resistor 21 and the last (2N-th) resistor 21 may have a large difference in resistance value. In contrast, when the resistors 21 are alternately connected, that is, the first and third resistors are connected to each other and the second and fourth resistors are connected to each other as shown in FIG. 3, it is possible to reduce the influence of in-plane variations in resistance. Therefore, with the layout configuration of FIG. 3, even when the resistors have a large interface resistance, it is possible to accurately form the resistors with low resistance values while reducing the influence of the in-plane variations of the resistors 21, thereby minutely generating gradation voltages.

### Embodiment 3

FIG. 4 is a structural diagram showing a resistance voltage divider circuit for a liquid crystal display driving apparatus according to Embodiment 3 of the present invention.

As shown in FIG. 4, a first resistor 33 is provided which has contacts 31 on both ends and a plurality of (four in FIG. 4) contacts 32-1 to 32-4 between both ends. Further, only on portions requiring low resistances, second resistors are provided so as to face the contacts 32-1 to 32-4 of the first resistor 33. In FIG. 4, a second resistor 34 having contacts 37 on both ends is provided in parallel with the first resistor 33 so as to face the contacts 32-1 and 32-2 of the first resistor 33, and two second resistors 35 and 36, each of which has contacts 37 on both ends, are provided in parallel with the first resistor 33 so as to face the contacts 32-3 and 32-4 of the first resistor 33.

Further, the contacts 32-1 and 32-2 of the first resistor 33 and the contacts 37 on both ends of the second resistor 34 are connected via gradation voltage output wires 38. The contacts 32-3 and 32-4 of the first resistor 33 and the contacts 37 on both ends of the two second resistors 35 and 36 are connected via gradation voltage output wires 39. Reference voltages V1 and V2 are inputted across (contacts 31) the first resistor 33 via a reference voltage supply wire (not shown), and gradation voltages V₇₁, V₇₂, V₇₃, and V₇₄ are generated on the junction points (wires 38 and 39) of the contacts 32-1 to 32-4 and 37 according to voltages divided by the first resistor 33.

To be specific, the resistance voltage divider circuit of FIG. 4 is formed as follows:

First, the resistors 33, 34, 35, and 36 formed by N+ polysilicon resistors are provided on a substrate. Then, the gradation voltage output wires 38 and 39, which intersect the resistors 33, 34, 35, and 36 and are made of a material such as aluminum, are provided on the resistors 33, 34, 35, and 36 via an interlayer insulating film (not shown). Subsequently, the resistors 33, 34, 35, and 36 and the gradation voltage output wires 38 and 39 are connected via the contacts 32-1 to 32-4 and 37 made of a material having a low resistance value (e.g., a metal compound of silicon that is called silicide).

According to Embodiment 3, the basic resistance voltage divider circuit for a liquid crystal display driving apparatus is constituted of the single first resistor 33, and the second resistors 34, 35, and 36 are connected in parallel, so that the resistors can be accurately formed with a low resistance value and gradation voltages can be generated minutely. Further, the second resistors 34, 35, and 36 are connected in parallel only on portions having low resistance values which are necessary for minutely generating gradation voltage differences. Thus, in contrast to a configuration having a number of resistors of equal lengths with a large layout area, the resistors are arranged in parallel only on portions necessary for low resistances, so that a layout area can be reduced.

### Embodiment 4

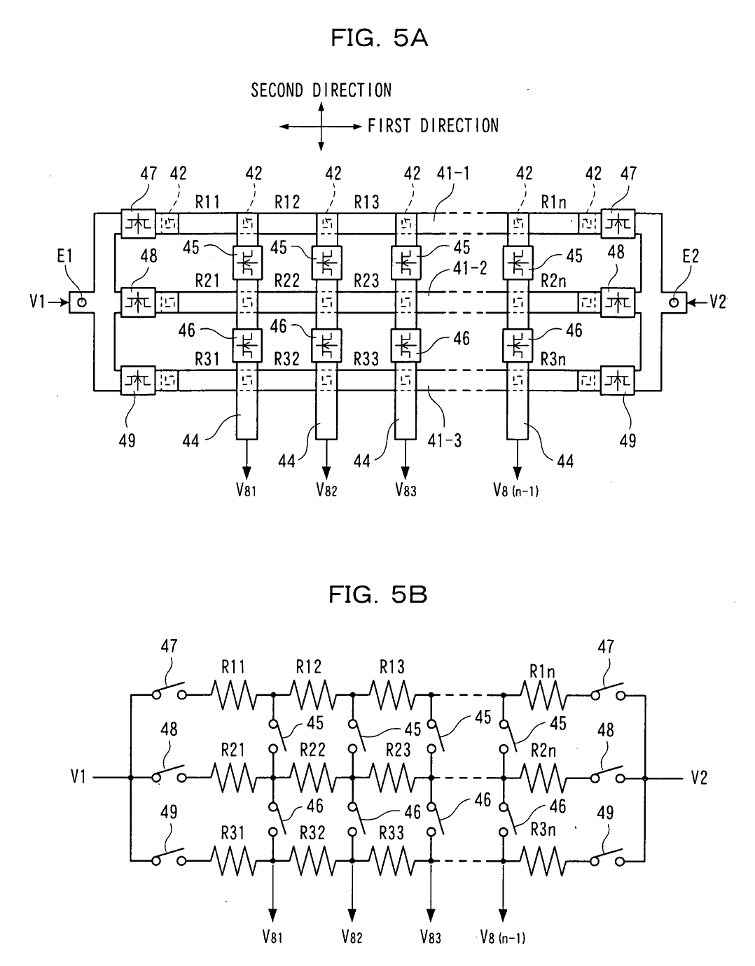

FIG. 5 is a structural diagram showing a resistance voltage divider circuit for a liquid crystal display driving apparatus according to Embodiment 4 of the present invention.

As shown in FIG. 5, a plurality of (threein FIG. 5) resistors 41 are provided in parallel the vertical direction of FIG. 5. The resistors 41 are almost equal in resistance value and have a plurality of ((n+1):n is a positive integer equal to or larger than 2) contacts 42, on which gradation voltages are extracted, at the equal positions with respect to the horizontal direction of FIG. 5. Resistance values between the contacts 42 of the resistors 41 have the relationship of R11:R12:R13: . . . :R1n=R21:R22:R23: . . . :R2n=R31:R32:R33: . . . :R3n where R11, R12, R13, . . . R1n represent resistance values between the contacts of a first resistor 41-1 of the resistors 41, R21, R22, R23, . . . R2n represent resistance values between the contacts of a second resistor 41-2, and R31, R32, R33, . . . R3n represent resistance values between the contacts of a third resistor 41-3.

The intermediate contacts 42 at the equal positions of the resistors 41 are connected by gradation voltage output wires 44 via first switches 45 and second switches 46 (the switches 45 and 46 are examples of a control switch) so as to connect the resistors 41 in parallel. A third switch 47, a fourth switch 48, and a fifth switch 49 (the switches 47, 48, and 49 are examples of a power supply switch) are connected to the contacts 42 on the ends of the resistors 41.

Then, a high voltage side reference voltage V1 is supplied from a first node E1 and a low voltage side reference voltage V2 is supplied from a second node E2 to the ends of the resistors 41 via the third switch 47, the fourth switch 48, and the fifth switch 49. With the supply of the high voltage side reference voltage V1 and the low voltage side reference voltage V2, γ gradation voltages V₈₁, V₈₂, . . . V₈₍ₙ₋₁₎ are outputted from the junction points of the intermediate contacts 42 via the first, second, . . . (n−1)-th gradation voltage output wires 44 according to voltages divided by the three resistors 41.

To be specific, the resistance voltage divider circuit of FIG. 5 is formed as follows:

First, the first resistor 41-1, the second resistor 41-2, and the third resistor 41-3 are arranged in parallel along a second direction on a substrate. The resistors are almost equal in length along a first direction (the horizontal direction of FIG. 5), are almost equal in-width along the second direction (the vertical direction of FIG. 5) orthogonal to the first direction, and are formed by N+ polysilicon resistors. That is, the resistors 41 (41-1, 41-2, 41-3) almost equal in resistance value are provided in parallel. Then, a gradation voltage output part is provided on the resistors 41 via an interlayer insulating film (not shown). The gradation voltage output part is constituted of the gradation voltage output wires 44 which are orthogonal to the resistors 41-(41-1, 41-2, 41-3) and are made of a material such as aluminum, and the first switch 45, the second switch 46, the third switch 47, the fourth switch 48, and the fifth switch 49 which are composed of P-channel MOS transistors. Subsequently, the resistors 41 and the gradation voltage output wires 44 are connected via the contacts 42 made of a material having a low resistance value (e.g., a metal compound of silicon that is called silicide).

According to Embodiment 4, the three resistors 41 almost equal in resistance value are connected in parallel, the intermediate contacts 42 at the equal positions with respect to the horizontal direction of FIG. 5 are connected, that is, the contacts 42 where the three resistors are almost equal in resistance value are connected so as to connect the nodes having equal voltages, and voltages from the node having equal voltages are outputted as gradation voltages, thereby accurately obtaining gradation voltages with low resistance values. By performing on/off control on the gradation voltage output wires 44, which output gradation voltages, via the first switch 45 and the second switch 46, it is possible to adjust the number of voltage dividing resistors R11, R12, R13, . . . R1n, R21, R22, R23, . . . R2n, R31, R32, R33, . . . R3n. With this configuration, it is possible to set and form resistors more minutely and obtain detailed gradation voltages necessary for the gradation voltage output wires 44. The third switch 47, the fourth switch 48, and the fifth switch 49 are provided between the reference voltages V1 and V2 and the resistors 41 and control is performed so as to turn off the switches 47, 48, and 49 when necessary, for example, when gradation voltages are not necessary. Thus, it is possible to isolate the resistors 41 and the reference voltages V1 and V2 from each other, thereby preventing an unnecessary current flow and reducing power consumption.

In Embodiments 1 to 4, the resistors are formed by N+ polysilicon resistors. The resistors may be formed by P+ polysilicon resistors, N+ diffused resistors, or P+ diffused resistors.

In Embodiment 4, the first switch 45, the second switch 46, the third switch 47, the fourth switch 48, and the fifth switch 49 are formed by P-channel MOS transistors. The switches may be formed by N-channel MOS transistors or combinations of a P-channel transistor and an N-channel MOS transistor.

Gradations can be formed with high accuracy by using the resistance voltage divider circuit of the present invention. Thus, the resistance voltage divider circuit of the present invention can be used in various forms. For example, the resistance voltage divider circuit is implemented as a drive which generates gradation voltages and driving voltages for driving a display device according to the gradation voltages and a display which is integrated with the drive so as to drive a plurality of display devices formed on a substrate.

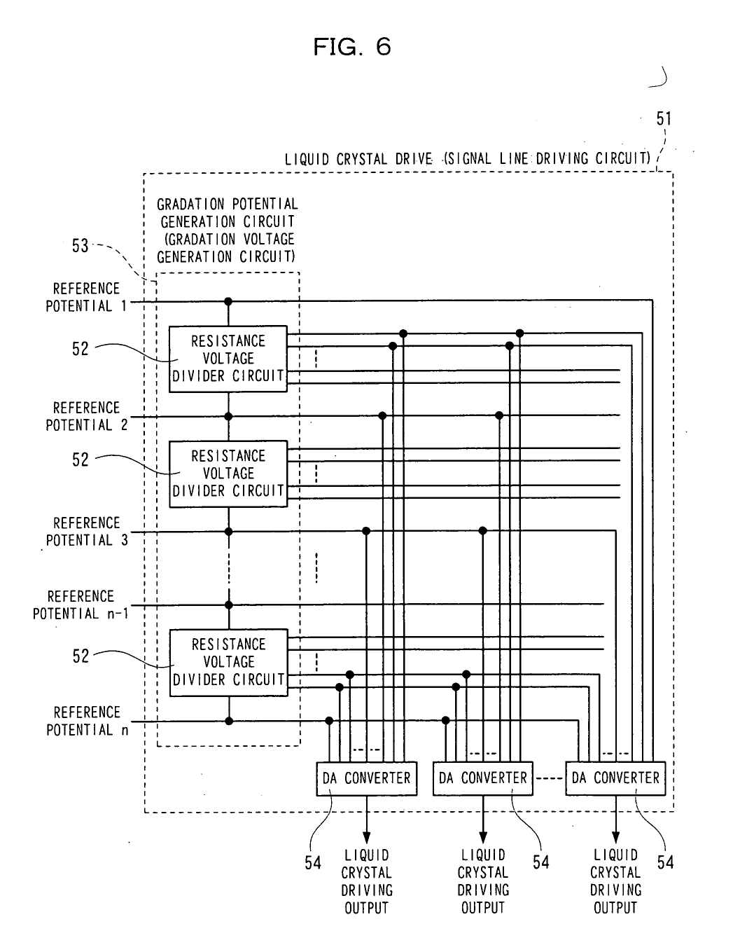

FIG. 6 is a structural diagram showing a liquid crystal display driving apparatus comprising a plurality of resistance voltage divider circuits according to the preferred embodiments (Embodiments 1 to 4) of the present invention.

As shown in FIG. 6, a liquid crystal display driving apparatus 51 is constituted of a gradation voltage generation circuit (gradation voltage generation circuit) 53, which is composed of a plurality of resistance voltage divider circuits 52, and DA converters (converter circuits) 54. Gradation voltages between reference voltages are generated from two reference voltages supplied by the resistance voltage divider circuits 52 of the gradation voltage generation circuit 53, and the gradation voltages are inputted to the DA converters 54. Driving voltages (analog voltages) for driving a plurality of liquid crystal elements are generated by the DA converters 54 according to the inputted gradation voltages and inputted digital command values (not shown).

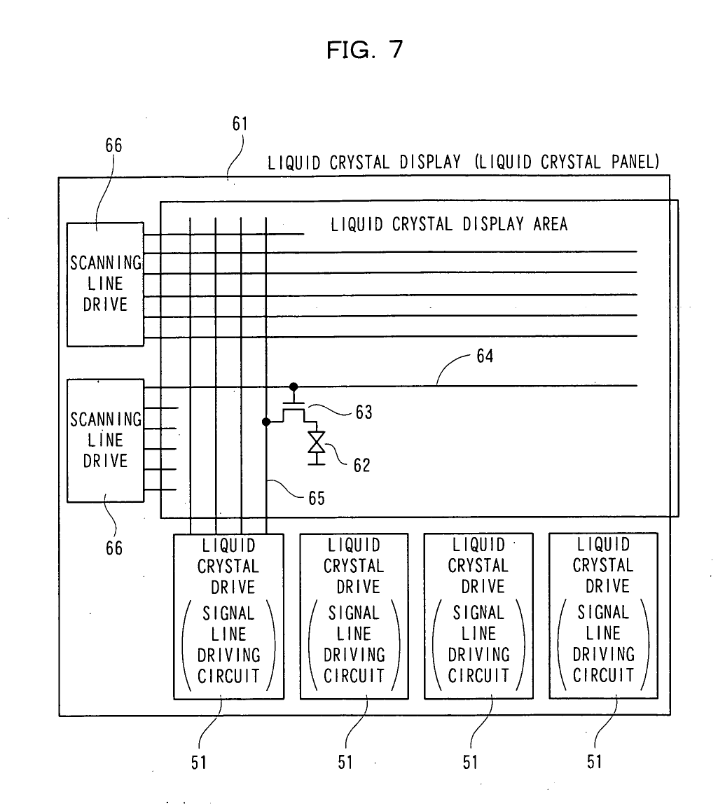

FIG. 7 is a structural diagram showing a liquid crystal display apparatus comprising the liquid crystal display driving apparatus 51 of FIG. 6 as a signal line driving circuit.

A liquid crystal display apparatus 61 comprises, in addition to the liquid crystal display driving apparatus 51, a plurality of liquid crystal elements 62 formed on a substrate, a plurality of TFTs (Thin Film Transistors) 63 connected to the liquid crystal elements 62, a plurality of scanning lines 64 connected to the gates of the plurality of TFTs 63, a plurality of drive wires 65 which are connected to the opposite ends of the plurality of TFTs 63 from the liquid crystal elements 62 and are driven by the liquid crystal display driving apparatuses 51, and scanning line drives 66 for driving the plurality of scanning lines 64.

According to the liquid crystal display driving apparatuses 51 or the liquid crystal display apparatus 61 configured thus, the liquid crystal elements 62 can be driven by accurate gradation voltages, thereby improving gradation display, i.e., the quality of display on a liquid crystal panel.

Although the embodiments described a liquid crystal as an example, the present invention is not limited to this example. Other display devices, e.g., organic EL devices also belong to the technical scope of the present invention as long as gradation voltages are inputted for driving in a display mode.

With the resistance voltage divider circuit of the present invention, it is possible to accurately form resistors with low resistance values and minutely generate gradation voltages. The resistance voltage divider circuit can be also applied to measuring instruments and controllers which require a plurality of reference voltages with high accuracy.

1. A resistance voltage divider circuit for generating a gradation voltage for driving a display device, comprising a plurality of resistors being equal in resistance value and having contacts at equal positions, wherein
the contacts at the equal positions of the resistors are connected to one another so as to connect the resistors in parallel, a reference voltage is inputted across the resistors connected in parallel, and a gradation voltage is generated on a junction point of the contact according to a voltage divided by the resistors.

2. The resistance voltage divider circuit according to claim 1, wherein the resistor is constituted of an N+ polysilicon resistor, a P+ polysilicon resistor, an N+ diffused resistor, or a P+ diffused resistor.

3. A liquid crystal display driving apparatus, comprising:
the resistance voltage divider circuit of claim 1, and
a converter circuit which outputs a driving voltage for driving a plurality of liquid crystal elements formed on a substrate, according to a gradation voltage outputted from the resistance voltage divider circuit and a command value.

4. A liquid crystal display apparatus, comprising:
the liquid crystal display driving apparatus of claim 3,
a plurality of liquid crystal elements formed on a substrate, and
drive wires formed on the substrate, each drive wire connected to the plurality of liquid crystal elements via a plurality of TFTs,
wherein the liquid crystal display driving apparatus is connected to the drive wires and drives the drive wires by outputting a driving voltage.

5. A resistance voltage divider circuit which generates a gradation voltage for driving a display device, comprising:
2N resistors (N is a positive integer equal to or larger than 2) which are arranged in sequence and are equal in resistance value;
connecting contacts provided at equal positions on ends of the resistors; and
contacts for outputting gradation voltage, the contacts being provided at the equal positions other than ends of a pair of adjacent (2M−1)-th and 2M-th resistors of the resistors (M is a positive integer satisfying M<N), wherein
the contacts for outputting gradation voltages at the equal positions of the pair of adjacent resistors are connected to each other, a reference voltage is inputted via the connecting contacts on ends of the first and second resistors and the connecting contacts on ends of the (2N−1)-th and 2N-th resistors of the resistors, the connecting contacts are connected such that all odd-numbered resistors from the first resistor to the (2N−1)-th resistor are connected in sequence with respect to the input of the reference voltage, the connecting contacts are connected such that all even-numbered resistors from the second resistor to the 2N-th resistor are connected in sequence with respect to the input of the reference voltage, and a gradation voltage is generated on a junction point of the contact for outputting a gradation voltage according to a voltage divided by the resistors.

6. The resistance voltage divider circuit according to claim 5, wherein the resistor is constituted of an N+ polysilicon resistor, a P+ polysilicon resistor, an N+ diffused resistor, or a P+ diffused resistor.

7. A liquid crystal display driving apparatus, comprising:
the resistance voltage divider circuit of claim 5; and
a converter circuit for outputting a driving voltage for driving a plurality of liquid crystal elements formed on a substrate, according to a gradation voltage outputted from the resistance voltage divider circuit and a command value.

8. A liquid crystal display apparatus, comprising:
the liquid crystal display driving apparatus of claim 7;
a plurality of liquid crystal elements formed on a substrate; and
drive wires formed on the substrate, each drive wire connected to the plurality of liquid crystal elements via a plurality of TFTs, wherein
the liquid crystal display driving apparatus is connected to the drive wires and drives the drive wires by outputting a driving voltage.

9. A resistance voltage divider circuit for generating a gradation voltage for driving a display device, comprising:
a first resistor having a plurality of contacts; and
a plurality of second resistors, each having contacts on both ends and being arranged on a predetermined portion so as to face the contacts of the first resistor, wherein
contacts of the first resistor and the contacts of the second resistors facing the first resistor are connected to one another, a reference voltage is inputted across the first resistor, and a gradation voltage is generated on a junction point of the contact according to a voltage divided by the resistors.

10. The resistance voltage divider circuit according to claim 9, wherein the first and second resistors are each constituted of an N+ polysilicon resistor, a P+ polysilicon resistor, an N+ diffused resistor, or a P+ diffused resistor.

11. A liquid crystal display driving apparatus, comprising:
the resistance voltage divider circuit of claim 9; and
a converter circuit for outputting a driving voltage for driving a plurality of liquid crystal elements formed on a substrate, according to a gradation voltage outputted from the resistance voltage divider circuit and a command value.

12. A liquid crystal display apparatus, comprising:
the liquid crystal display driving apparatus of claim 11;
a plurality of liquid crystal elements formed on a substrate; and
drive wires formed on the substrate, each drive wire connected to the plurality of liquid crystal elements via a plurality of TFTs, wherein
the liquid crystal display driving apparatus is connected to the drive wires and drives the drive wires by outputting a driving voltage.

13. A resistance voltage divider circuit for generating a gradation voltage for driving a display device, comprising a plurality of resistors being equal in resistance value and having contacts at equal positions, wherein
the contacts at the equal positions of the resistors are connected to one another via a plurality of control switches so as to connect the resistors in parallel,
a plurality of power supply switches are provided on both ends of the resistors,
a reference voltage is inputted across the resistors via the plurality of power supply switches, and
a gradation voltage is generated on a junction point of the contact according to a voltage divided by the resistors.

14. The resistance voltage divider circuit according to claim 13, wherein the control and power supply switches include an N-channel MOS transistor, a P-channel MOS transistor, or both of the N-channel MOS transistor and the P-channel MOS transistor.

15. The resistance voltage divider circuit according to claim 13, wherein the resistor is constituted of an N+ polysilicon resistor, a P+ polysilicon resistor, an N+ diffused resistor, or a P+ diffused resistor.

16. A liquid crystal display driving apparatus, comprising:
the resistance voltage divider circuit of claim 13; and
a converter circuit for outputting a driving voltage for driving a plurality of liquid crystal elements formed on a substrate, according to a gradation voltage outputted from the resistance voltage divider circuit and a command value.

17. A liquid crystal display apparatus, comprising:
the liquid crystal display driving apparatus of claim 16;
a plurality of liquid crystal elements formed on a substrate; and
drive wires formed on the substrate, each drive wire connected to the plurality of liquid crystal elements via a plurality of TFTs, wherein
the liquid crystal display driving apparatus is connected to the drive wires and drives the drive wires by outputting a driving voltage.

18. A resistance voltage divider circuit for generating a gradation voltage for driving a display device, comprising:
a first resistor provided between a first node for supplying a high voltage side reference voltage and a second node for supplying a low voltage side reference voltage;
a second resistor; and
a first gradation voltage output wire for connecting nodes equal in voltage on the first resistor and the second resistor via a first contact on the first resistor and a first contact on the second resistor, and outputting as a gradation voltage a voltage outputted from the nodes equal in voltage.

19. The resistance voltage divider circuit according to claim 18, wherein the second resistor is formed in parallel with a part of the first resistor, and the circuit further comprises a second gradation voltage output wire which connects nodes equal in voltage on the first resistor and the second resistor via a second contact on the first resistor and a second contact on the second resistor, and outputs as a gradation voltage a voltage outputted from the nodes equal in voltage.

20. The resistance voltage divider circuit according to claim 18, wherein the second resistor is provided between the first node and the second node.

21. The resistance voltage divider circuit according to claim 20, wherein the first resistor and the second resistor have a substantially equal length along a first direction and a substantially equal width along a second direction orthogonal to the first direction, and are arranged in parallel along the second direction.

22. The resistance voltage divider circuit according to claim 21, wherein the first gradation voltage output wire connects the first contact on the first resistor and the first contact on the second resistor, and outputs the gradation voltage in the second direction, the contacts being arranged substantially at equal positions with respect to the first direction.

23. The resistance voltage divider circuit according to claim 22, further comprising a third resistor provided between the first node and the second node, the third resistor being substantially equal in length to the first and second resistors along the first direction and being substantially equal in width to the first and second resistors along the second direction orthogonal to the first direction, the third resistor being arranged in parallel with the first and second resistors along the second direction, wherein
the first gradation voltage output wire connects the first contact on the first resistor, the first contact on the second resistor, and a first contact on the third resistor, the contacts being arranged substantially at the equal positions with respect to the first direction.

24. The resistance voltage divider circuit according to claim 23, further comprising a first switch provided between the first contact on the first resistor and the first contact on the second resistor on the first gradation voltage output wire, and a second switch provided between the first contact on the second resistor and the first contact on the third resistor on the first gradation voltage output wire, wherein
the first switch and the second switch are subjected to on/off control.

25. The resistance voltage divider circuit according to claim 24, further comprising third to fifth switches provided between the first node or the second node and junction points of the first to third resistors, wherein
when an output of the gradation voltage is unnecessary, control is performed to turn off the third to fifth switches.

26. The resistance voltage divider circuit according to claim 25, wherein the first to fifth switches include an N-channel MOS transistor, a P-channel MOS transistor, or both of the N-channel MOS transistor and the P-channel MOS transistor.

27. The resistance voltage divider circuit according to claim 23, further comprising third to fifth switches provided between the first node or the second node and junction points of the first to third resistors, wherein
when an output of the gradation voltage is unnecessary, control is performed to turn off the third to fifth switches.

28. The resistance voltage divider circuit according to claim 27, wherein the third to fifth switches include an N-channel MOS transistor, a P-channel MOS transistor, or both of the N-channel MOS transistor and the P-channel MOS transistor.

29. The resistance voltage divider circuit according to claim 18, wherein the resistor comprises one of an N+ polysilicon resistor, a P+ polysilicon resistor, an N+ diffused resistor, and a P+ diffused resistor.

30. A liquid crystal display driving apparatus, comprising:
the resistance voltage divider circuit of claim 18; and
a converter circuit for outputting a driving voltage for driving a plurality of liquid crystal elements formed on a substrate, according to a gradation voltage outputted from the resistance voltage divider circuit and a command value.

31. A liquid crystal display apparatus, comprising:
the liquid crystal display driving apparatus of claim 30;
a plurality of liquid crystal elements formed on a substrate; and
drive wires formed on the substrate, each drive wire connected to the plurality of liquid crystal elements via a plurality of TFTs, wherein
the liquid crystal display driving apparatus is connected to the drive wires and drives the drive wires by outputting a driving voltage.
